(19) United States
(12) Patent Application Publication
(10) Pub. No.: US 2007/0120256 A1
(43) Pub. Date: May 31, 2007

(54) Reinforced interconnection structures

(75) Inventor: Hsien-Wei Chen, Tainan (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/287,347

(22) Filed: Nov. 28, 2005

(51) Int. Cl. H01L 23/52; H01L 23/48; H01L 29/40

(52) U.S. Cl. 257/758

(57) ABSTRACT

Reinforced interconnection structures are provided. A reinforced interconnection structure comprises a first conductive layer formed in a first dielectric layer. A second conductive layer is formed in a second dielectric layer which overlies the first dielectric layer. A third conductive layer formed in a third dielectric layer which overlies the second dielectric layer, wherein the second conductive layer is a continuous conductive layer with at least one dielectric via formed therein, having a smaller surface area than that of the first and third conductive layers, and the first and third conductive layers are bulk conductive layers

### BACKGROUND

The present invention relates to semiconductor device fabrication, and more particularly to a structurally reinforced interconnect structure for a semiconductor device.

In the semiconductor process, a plurality of dies, each containing integrated circuits, are fabricated on a semiconductor wafer at one time. Advances in semiconductor processing technologies, such as high-resolution photolithography and anisotropic plasma etching, have dramatically reduced the feature sizes of formed semiconductor devices in the integrated circuit and increased the device packing density. Other process technologies, such as die scribing for separating dies within a wafer and fuse blowing for improving the yield of circuit elements in a dynamic random access memory (DRAM), however, induce lateral stresses which spread along boundaries between the multi-layer interconnection and adjacent dielectric layers and cause microcracking and delamination near a via portion of the multi-layer interconnection while the via portion is formed of one or more isolated metal plugs. The lateral stresses may further progress into a core circuitry of an integrated circuit, thus reducing yield and performance thereof.

Thus, a reinforced interconnection structure, whereby multi-layer interconnection with strong resistance to lateral stresses at via portions thereof, is desired.

Reinforced interconnection structures are provided. An exemplary embodiment of a reinforced interconnection structure comprises a first conductive layer formed in a first dielectric layer. A second conductive layer is formed in a second dielectric layer which overlies the first dielectric layer. A third conductive layer formed in a third dielectric layer which overlies the second dielectric layer, wherein the second conductive layer is a continuous conductive layer with at least one dielectric via formed therein, having a smaller surface than that of the first and third conductive layers, and the first and third conductive layers are bulk conductive layers.

An embodiment of an integrated circuit chip, adopting the above reinforced interconnection structure, comprises a device region for forming semiconductor devices therein. A seal ring region surrounds the active region. A peripheral region surrounds the seal ring region, wherein the seal ring region comprises a substrate and the above reinforced interconnection structure disposed thereon. A top passivation layer is formed over the third conductive layer and the third dielectric layer.

An embodiment of a fuse structure, using the above reinforced interconnection structure, comprises a substrate. A pair of first conductive layers respectively formed in a first dielectric layer overly the substrate. A pair of second conductive layers respectively formed in a second dielectric layer overly the first dielectric layer. A pair of third conductive layers respectively formed in a third dielectric layer overly the second dielectric layer, wherein the second conductive layers are continuous conductive layers with at least one dielectric via formed therein, having a surface smaller than that of the first and third conductive layers, and the first and third conductive layers are bulk conductive layers. A fourth dielectric layer forms over the third dielectric layer. A fourth conductive layer overlies the fourth dielectric layer, having two downward protrusions formed through the fourth dielectric layer, electrically connecting each of the third conductive layers.

An embodiment of a method for forming a reinforced interconnection structure comprises providing a first dielectric layer with a first conductive layer formed therein. A second dielectric layer is provided with a second conductive layer formed therein and overlies the first dielectric layer. A third dielectric layer is provided with a third conductive layer formed therein and overlies the second dielectric layer, wherein the second conductive layer is formed as a continuous conductive layer with at least one dielectric via therein, having a surface smaller than that of the first and third conductive layers, and the first and third conductive layers are formed as bulk conductive layers.

A detailed description is given in the following embodiments with reference to the accompanying drawings.

### BRIEF DESCRIPTION OF THE DRAWINGS

The invention can be more fully understood by reading the subsequent detailed description and examples with reference made to the accompanying drawings, wherein:

FIG. 1 is a cross section of a reinforced interconnection structure according to an embodiment of the invention;

FIGS. 2-4 are schematic top views of the conductive via portion of the reinforced interconnection structure of FIG. 1, according to various embodiments;

FIG. 5 is a schematic top of an integrated circuit chip with a seal ring region adopting the reinforced interconnection structure of the invention;

FIG. 6 is a schematic diagram taken along line 6-6 of FIG. 5, showing a cross section of a portion of the IC chip within the seal ring region;

FIG. 7 is a schematic diagram showing a cross section of a fuse structure adopting the reinforced interconnection structure of the invention;

FIG. 8 is a schematic diagram showing a cross section of a fuse structure adopting the reinforced interconnection structure of the invention, protected by two additional reinforced interconnection structures; and

FIG. 9 is a schematic diagram showing a top view of an exemplary arrangement of the fuse structure and the additional reinforced interconnection structures illustrated in FIG. 8.

### DESCRIPTION

Reinforced interconnect structures will now be described here in greater detail. The invention can potentially reduced damages of microcracking and delamination induced by processing techniques such as die scribing or fuse bombing with in an interconnection structure, and ensures IC chip performances. In some embodiments, this can be accomplished by forming a reinforced interconnection structure with a via portion thereof formed of a continuous conductive layer with at least one dielectric via therein.

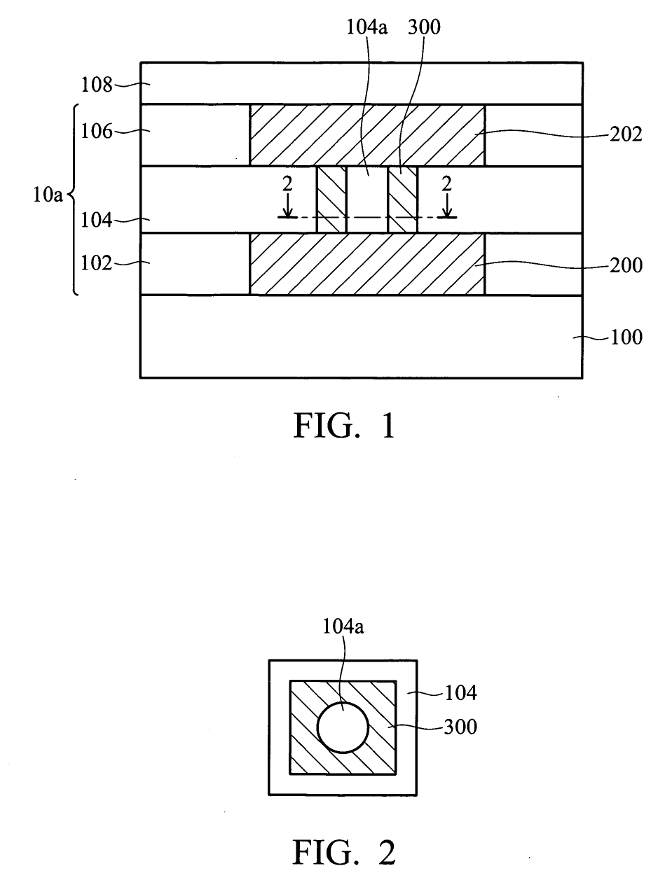

Referring to the drawings, FIG. 1 is a schematic diagram illustrating a cross section of an embodiment of a reinforced interconnection structure 10a. As shown in FIG. 1, the reinforced interconnection structure 10a is formed over an integrated circuit (IC) structure 100 which may comprise a semiconductor substrate (not shown) having semiconductor devices and multilayer interconnection structures formed thereon or merely a semiconductor substrate with stacked dielectric layers thereon. The semiconductor devices can be either active or passive devices formed on a semiconductor substrate, and the multi-layer interconnection structures can be multiple metallization layers supported and spaced by inter-layer dielectric. The semiconductor devices and multi-layer interconnection structures formed which may be formed, however, are not shown in the integrated circuit structure 100 for simplicity.

The reinforced interconnection structure 10a comprises a plurality of dielectric layers 102, 104, 106 and 108 sequentially formed over the IC structure 100. The dielectric layers 102 and 106 are respectively formed with a bulk conductive layer 200 and 202 therein, functioning as, for example, a conductive line. The dielectric layer 104 disposed between the dielectric layers 102 and 106 is formed with a conductive layer 300 therein. In FIG. 1, the conductive layer 300 is illustrated as a conductive layer formed with one dielectric via 104a through the dielectric layer 104. The conductive layer 30b is therefore formed in a continuous manner to function as a conductive via of the reinforced interconnect structure 10a. In the dielectric layer 108 formed over the dielectric layer 106, other fabrication can be performed sequentially formed or the dielectric layer 108 can function as a top-most passivation to the underlying structure. Since the via portion of the reinforced interconnect structure 10a is formed in such continuous manner, a larger contacting surface than the conventional via formed of one or more isolated metal plugs is provided between the conductive layer 106 and 102, thus improving adhesions therebetween. Resistances of the reinforced interconnect structure 10a against the laterally progressing mechanical stresses induced by semiconductor processing, such as die scribing or fuse blowing, is thus improved.

As shown in FIG. 1, although one dielectric via 104a is formed within the conductive layer 300 but is not limited thereto, a plurality of dielectric vias 104a can be formed and, preferably, a plurality of dielectric vias 104a is formed in the conductive layer 300 to form a reinforced via with an array of dielectric vias 104a. Typically, the dielectric via 104a may occupy not more than about 20-80% (by area) of the conductive layer 300. The conductive layer 300 is formed with a surface area smaller than that of the conductive layers 200 and 202, and is overlapped by the conductive layers 200 and 202, not shown here, for simplicity. Ratios between the conductive layer 200/202 and 300 is about 5:1 to 1.25:1.

Fabrication of the reinforced interconnection structure 10a is described in the following. The integrated circuit (IC) structure 100 is first provided as a base. The dielectric layer with the conductive layer 102 is then formed over the IC structure 100 by, for example, conventional line fabrication techniques or single damascene process. Next, the dielectric layer 104 with the conductive layer 300 and the dielectric layer 106 with the conductive layer 202 are then provided over the dielectric layer 102. The conductive layers 202 and 300 can be respectively formed in each dielectric layer (104 and 106) by conventional line fabrication techniques or single damascene process or simultaneously formed in the dielectric layers (104 and 106) by dual damascene process to thereby form the reinforced interconnection structure 10a. An addition dielectric layer 108 is then formed over the reinforced interconnection structure 10a for sequential fabrication or functioning as a top-most passivation. The conductive layers 200, 202 and 300 may comprise aluminum, copper, or alloys thereof depending on used fabrication techniques. The above layers can be layers of forming other devices and fabrication of the reinforced interconnection structure 10a can thus be easily integrated into a conventional device fabrication.

Although only a reinforced interconnection structure 10a is illustrated in FIG. 1, another reinforced interconnection structure 10a can also be form to be stacked over the reinforced interconnection structure 10a of FIG. 1, or over the dielectric layer 108, or between the reinforced interconnection structure 10a of FIG. 1 and the IC structure 100, thus providing various composite reinforced interconnection structures not limited by that illustrated in FIG. 1.

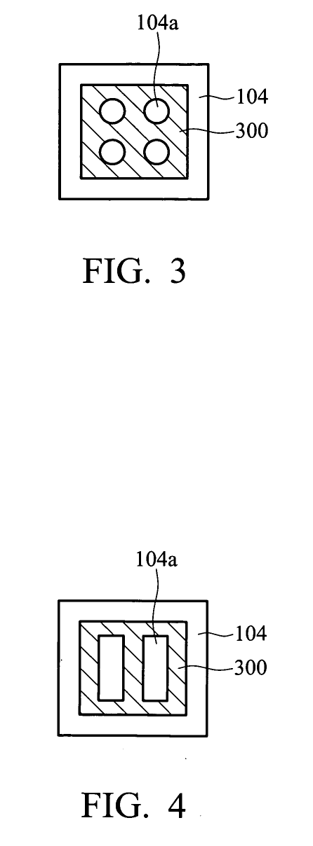

FIGS. 2-4 are examples showing various examples for forming the dielectric via 104a in the conductive layer 300. As shown in FIGS. 2-3, one or mote dielectric vias 104a can be formed in the conductive layer 300 in grid patterns or in parallel slot patterns, as shown in FIG. 4. Shape of the dielectric via 104a is illustrated as a circle or a rectangular bar, but is not limited thereto. The dielectric via 104a can also be formed in other shape, such as hexagon or other polygon.

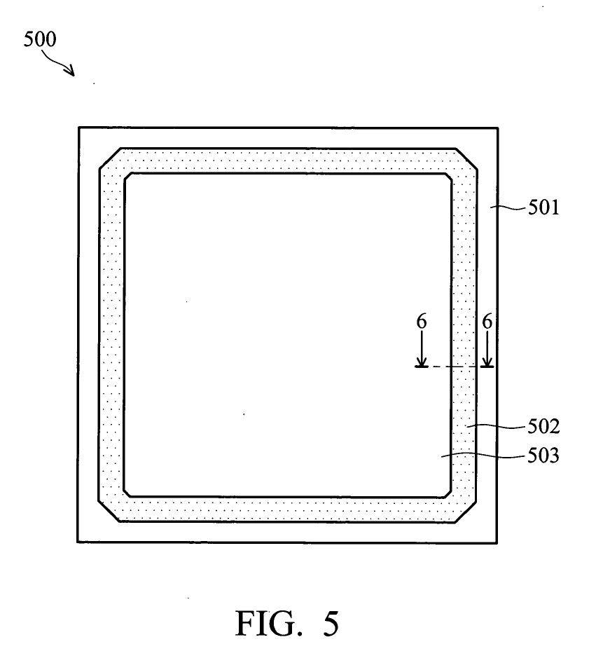

FIG. 5 illustrates a schematic top of an integrated circuit (IC) chip 500 with a seal ring region 502 adopting. reinforced interconnection structures similar to the one mentioned above. In FIG. 5, the IC chip 500 is provided with a device region 503 for forming semiconductor devices and a peripheral region 501 separated by a seal ring region 502. The seal ring region 502 surrounds the device area 503 and comprises a reinforced interconnection structure similar to that described above.

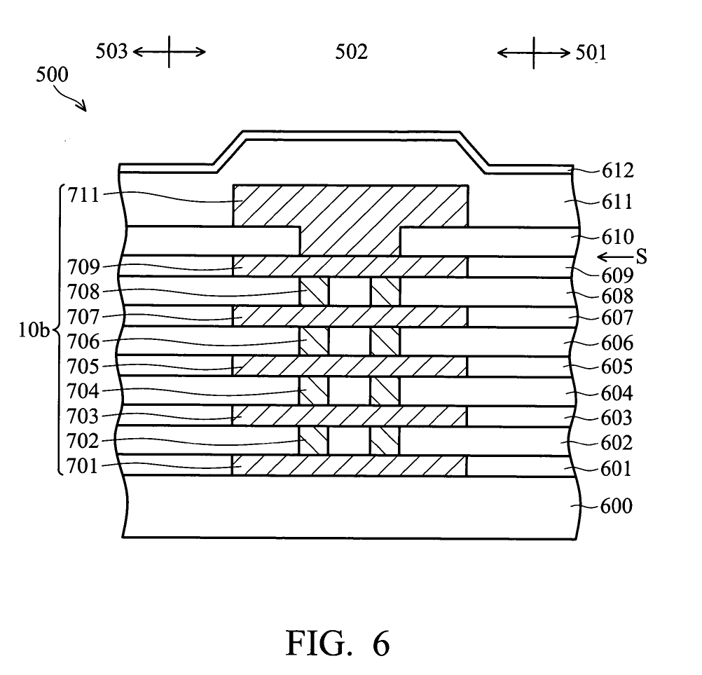

FIG. 6 is a schematic diagram taken along line 6-6 of FIG. 5, shows a cross section of a portion of the IC chip 500 in the seal ring region. A substrate 600 is first provided. The substrate 600 may comprise underlying layers, devices, junctions, and other features (not shown) and is illustrated with a planar surface, for simplicity. As shown in FIG. 6, a reinforced interconnection structure 10b similar to that illustrated in FIG. 1 is formed through dielectric layers 601-611 sequentially formed over the substrate 600, comprising bulk conductive layers 701, 703, 705, 707, 709, 711 and conductive layers 702, 704, 706, 708, having dielectric vias therein, stacked by turns. A dielectric layer 612 is formed over the dielectric layer 612, functioning as a top most passivation.

As shown in FIG. 6, the reinforced interconnection structure 10b here can be viewed as a repeated stacking structure of the reinforced interconnection structure 10a illustrated in FIG. 1 since die scribing is performed on the dielectric layers at a place within the peripheral region 501 and induces mechanical stresses S may laterally progress along boundaries between the dielectric layers (referring to the dielectric layers 601-611). Design rules and via arrangement of the conductive layers 702, 704, 706, 708 with at least one dielectric via formed therein, functioning as via portion of the reinforced interconnection structure 10b, is similar to that illustrated in FIG. 1 and is not described here again, for simplicity. Although the reinforced interconnection structure 10b illustrated in FIG. 6 is a composite reinforced interconnection structure formed by repeating the reinforced interconnection structure 10a of FIG. 1, the reinforced interconnection structure 10a can also merely comprise one such reinforced interconnection structure 10 of FIG. 1 and is not limited to that shown in FIG. 6.

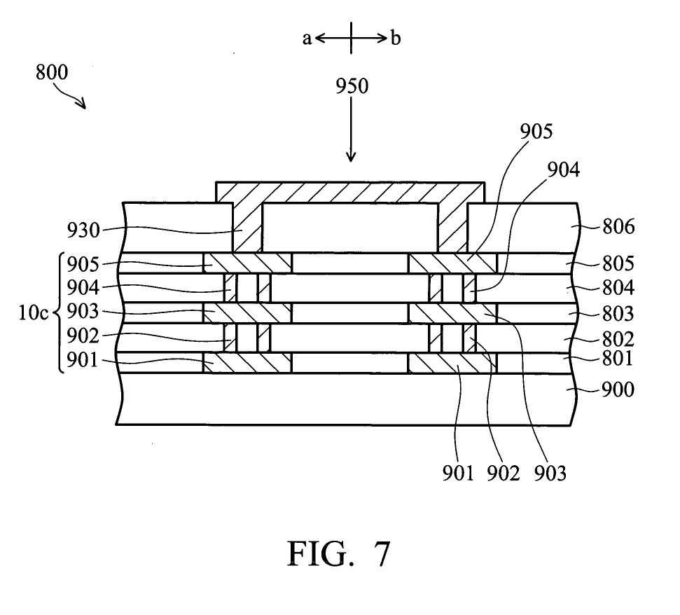

Moreover, the reinforced interconnection structure 10a of FIG. 1 is applicable for a fuse structure 800 of an IC device, for example a DRAM device, illustrated in FIG. 7. FIG. 7 shows a cross section of the fuse structure 800 of a portion of the IC device.

As shown in FIG. 7, a reinforced interconnection structure 10c similar to the reinforced interconnection structure 10a of FIG. 1 is illustrated. A substrate 900 is first provided. The substrate 900 may comprise underlying layers, devices, junctions, memory arrays, and other features (not shown) and is illustrated with a planar surface, for simplicity. As shown in FIG. 7, a pair of reinforced interconnection structures 10c similar to that illustrated in FIG. 1 are respectively formed through dielectric layers 801-806 sequentially formed over the substrate 900 to electrically connect memory arrays (not shown) in areas a and b, each is formed with a plurality bulk conductive layers 901, 903, 905 and conductive layers 902, 904, having a dielectric via therein, stacked by turns. A dielectric layer 806 is formed over the dielectric layer 805 and a fuse layer 930 is formed over the dielectric layer 806 with two downward protrusions formed therethrough, respectively connecting the reinforced interconnection structures 10c thereunder.

As shown in FIG. 7, each of the reinforced interconnection structure 10c here can be viewed as a repeated stacking structure of the reinforced interconnection structure 10a illustrated in FIG. 1 since fuse blowing may performed at a position 950 of the fuse layer 930 when the memory array within the area a or b is disorder, inducing mechanical stresses (not shown) may laterally progress along boundaries between the dielectric layers (referring to the dielectric layers 801-806). Design rules and via arrangement of the conductive layers 902, 904, with at least one dielectric via formed therein, functioning as via portion of the reinforced interconnection structure 10c, is similar to that illustrated in FIG. 1 and is not described here again, for simplicity. Although the reinforced interconnection structure 10c illustrated in FIG. 7 is a composite reinforced interconnection structure formed by repeating the reinforced-interconnection structure 10a of FIG. 1, the reinforced interconnection structure 10c can also merely comprise one reinforced interconnection structure 10a of FIG. 1 and is not limited by that shown in FIG. 7.

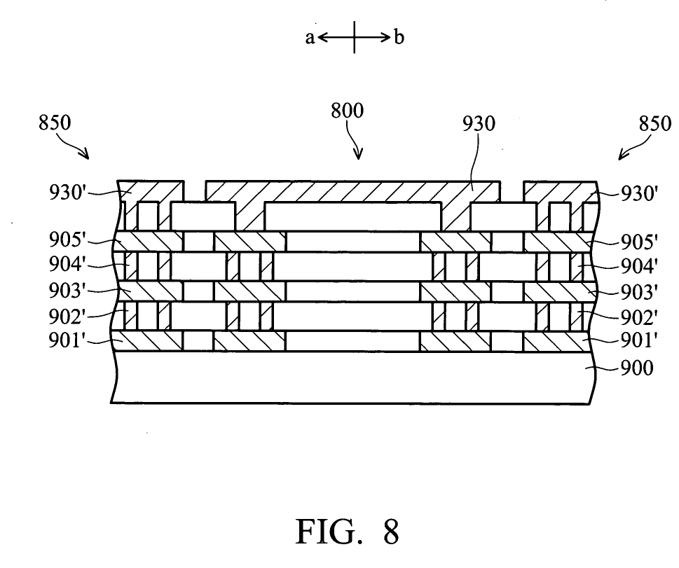

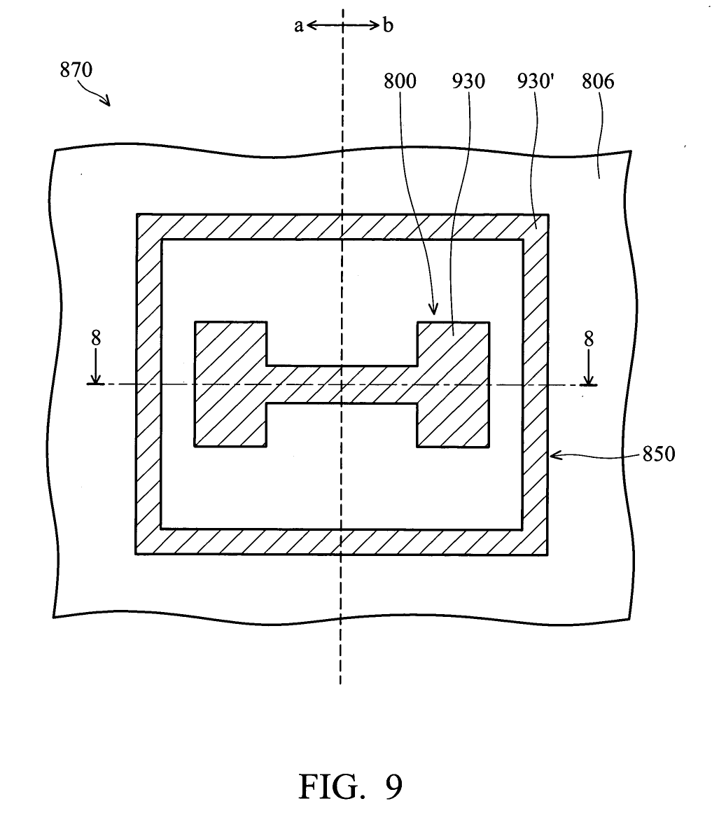

Typically but not necessarily, additional reinforced interconnection structures 850 similar to the reinforced interconnection structure 10a of FIG. 1 is illustrated can be further provided in the areas a and b from a side adjacent to the fuse structure 800, thereby providing additional mechanical protection against progresses of microcracking and delamination that may induced during fuse blowing of the fuse structure 800, as shown in FIG. 8. Herein, each of the reinforced interconnection structures 850 in FIG. 8 includes a plurality of dielectric layers 801-806 sequentially formed over the substrate 900, having a plurality bulk conductive layers 901′, 903′, 905′ and conductive layers 902′, 904′, 930′ with a dielectric via therein, stacked by turns. FIG. 9 shows an top view of an integrated circuit chip 870 having the fuse structure 800 protected by the reinforced interconnection structures 850. As shown in FIG. 9, the reinforced interconnection structures 850 form as a seal ring surrounding the fuse structure to thereby prevent progresses of microcracking and delamination that may induced during fuse blowing of the fuse structure 800.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A reinforced interconnection structure, comprising:
a first conductive layer formed in a first dielectric layer;
a second conductive layer formed in a second dielectric layer, overlying the first dielectric layer; and
a third conductive layer formed in a third dielectric layer, overlying the second dielectric layer, wherein the second conductive layer is a continuous conductive layer with at least one dielectric via formed therein, having a smaller surface than that of the first and third conductive layers, and the first and third conductive layers are bulk conductive layers.

2. The reinforced interconnection structure of claim 1, wherein the dielectric via occupies not more than about 20-80% (by area) of the second conductive layer.

3. The reinforced interconnection structure of claim 1, wherein a surface ratio between the second conductive layer and the first/third conductive layer is about 5:1-1.25:1.

4. The reinforced interconnection structure of claim 1, wherein the second conductive layer comprises a plurality of dielectric vias formed in grid or slot patterns.

5. An integrated circuit chip, comprising:
an active region for forming semiconductor devices therein;
a seal ring region surrounding the active area; and
a peripheral region surrounding the seal ring area,
wherein the seal ring region comprising:
a substrate;
a reinforced interconnection structure of claim 1, overlying the substrate; and
a top passivation layer over the third conductive layer and the third dielectric layer.

6. The integrated circuit chip of claim 5, wherein the dielectric via occupies not more than about 20-80% (by area) of the second conductive layer.

7. The integrated circuit chip of claim 5, wherein a surface ratio between the second conductive layer and, the first/third conductive layer is about 5:1-1.25:1.

8. The integrated circuit chip of claim 5, wherein the second conductive layer comprises a plurality of dielectric vias formed in grid patterns or slot patterns.

9. The integrated circuit chip of claim 5, wherein the second conductive layer is formed in a continuous phase, having at least one dielectric via formed therein.

10. A fuse structure for semiconductor devices, comprising:
a substrate;
a pair of first conductive layers respectively formed in a first dielectric layer, overlying the substrate;
a pair of second conductive layers respectively formed in a second dielectric layer, overlying the first dielectric layer; and
a pair of third conductive layers respectively formed in a third dielectric layer, overlying the second dielectric layer, wherein the second conductive layers are continuous conductive layers with at least one dielectric via formed therein, having smaller surfaces than that of the first and third conductive layers, and the first and third conductive layers are bulk conductive layers;
a fourth dielectric layer over the third dielectric layer; and
a fourth conductive layer overlying the fourth dielectric layer, having two downward protrusions formed through the fourth dielectric layer to electrically connect each of the third conductive layers.

11. The fuse structure of claim 10, wherein the second conductive layer comprises a plurality of dielectric vias formed in grid or slot patterns.

12. The fuse structure of claim 10, wherein the first, second, third, and fourth conductive layers comprise copper, aluminum or alloys thereof.

13. A method for forming a reinforced interconnection structure, comprising:
providing a first dielectric layer with a first conductive layer formed therein;
providing a second dielectric layer with a second conductive layer formed therein, overlying the first dielectric layer; and
providing a third dielectric layer with a third conductive layer formed therein, overlying the second dielectric layer, wherein the second conductive layer is formed as a continuous conductive layer with at least one dielectric via therein, having a smaller surface than that of the first and third conductive layers, and the first and third conductive layers are bulk conductive layers.

14. The method of claim 13, the dielectric via occupies not more than about 20-80% (by area) of the second conductive layer.

15. The method of claim 13, wherein the second conductive layer comprises a plurality of dielectric vias formed in grid or slot patterns.

16. An integrated circuit chip, comprising:
a fuse structure over in substrate; and
a seal ring over the substrate, surrounding the fuse structure, wherein the seal ring comprises a reinforced interconnection structure of claim 1.

17. The integrated circuit chip of claim 16, wherein the dielectric via occupies not more than about 20-80% (by area) of the second conductive layer.

18. The integrated circuit chip of claim 16, wherein a surface ratio between the second conductive layer and the first/third conductive layer is about 5:1-1.25:1.

19. The integrated circuit chip of claim 16, wherein the second conductive layer comprises a plurality of dielectric vias formed in grid patterns or slot patterns.

20. The integrated circuit chip of claim 16, wherein the second conductive layer is formed in a continuous phase, having at least one dielectric via formed therein.
